(19) United States
(12) Patent Application Publication
(10) Pub. No.: US 2025/0133816 A1
(43) Pub. Date: Apr. 24, 2025

(54) STACKED FET WITH ASYMMETRIC CELL BOUNDARY

(71) Applicant: INTERNATIONAL BUSINESS MACHINES CORPORATION, ARMONK, NY (US)

(72) Inventors: Ruilong Xie, Niskayuna, NY (US); Kisik Choi, Watervliet, NY (US); Shay Reboh, Guilderland, NY (US); Lawrence A. Clevenger, Saratoga Springs, NY (US); Brent A. Anderson, Jericho, VT (US); Albert M. Chu, Nashua, NH (US); Nicholas Anthony Lanzillo, Wynantskill, NY (US); Reinaldo Vega, Mahopac, NY (US)

(21) Appl. No.: 18/489,056

(22) Filed: Oct. 18, 2023

(51) Int. Cl. H01L 27/088; H01L 21/8234; H01L 23/528; H01L 29/06; H01L 29/417; H01L 29/423; H01L 29/66; H01L 29/775; H01L 29/786

(52) U.S. Cl. CPC H10D 84/83; H01L 23/5286; H10D 30/014; H10D 30/43; H10D 30/6735; H10D 30/6757; H10D 62/121; H10D 64/256; H10D 84/0149; H10D 84/0151; H10D 84/038

(57) ABSTRACT

Embodiments of present invention provide a semiconductor structure. The structure includes a first cell unit including a first set of field-effect-transistors (FETs), a first cell boundary made of a first gate cut region, and a second cell boundary made of a second gate cut region; a second cell unit including a second set of FETs, a third cell boundary made of a third gate cut region, and a fourth cell boundary made of the first gate cut region; and a third cell unit including a third set of FETs, a fifth cell boundary made of the second gate cut region, and a sixth cell boundary made of a fourth gate cut region, where the first and third gate cut regions have a first width and the second and fourth gate cut region has a second width larger than the first width. A method of forming the same is also provided.

### BACKGROUND

The present application relates to manufacturing of semiconductor integrated circuits. More particularly, it relates to forming stacked transistor cell with asymmetric cell boundary.

As semiconductor industry moves towards smaller node such as, for example, 5-nm node and beyond, field-effect-transistors (FETs) are aggressively scaled to fit into reduced footprint or real estate, which is often dictated by the node size, with increased device density. In addition to scaling, transistors may be stacked together to further increase the device density. For example, one nanosheet transistor may be stacked on top of another nanosheet transistor thereby doubling the total number of transistors in a fixed real estate area.

In a stacked transistor scheme, even though the available number of transistors may be made to double, there still exists the need to provide signal routing and power supply functions to the transistors both at the top and at the bottom. Even with the recent introduction of backside power rail and backside power distribution network, there is the need for cell design that can provide a good balance between cell height and flexibility for power and signal routing.

### SUMMARY

Embodiments of present invention provide a semiconductor structure. The structure includes a cell unit, the cell unit including a first field-effect-transistor (FET) stacked on top of a second FET; a first cell boundary made of a first gate cut region with a first width; and a second cell boundary made of a second gate cut region with a second width, where the second width of the second gate cut region is wider than the first width of the first gate cut region. In other words, the cell unit has asymmetric boundary, and the use of a wider second gate cut region as a boundary enables the cell unit to have a smaller cell height because the wider second gate cut region may be formed to include a conductive via for added S/D accessibility of the cell unit.

According to one embodiment, where the cell unit is a first cell unit, the structure further includes a second cell unit, the second cell unit including a third FET stacked on top of a fourth FET; and a third cell boundary made of the second gate cut region with the second width; and a fourth cell boundary made of a third gate cut region with a third width, where the third width of the third gate cut region is substantially same as the first width of the first gate cut region and is narrower than the second width of the second gate cut region, and wherein the first cell unit and the second cell unit has a same cell height. The first and the second cell unit may be formed to share a same wider second gate cut region.

In one embodiment, a source/drain (S/D) region of the first FET and a S/D region of the third FET are mirror-symmetry with respect to the second gate cut region, and a S/D region of the second FET and a S/D region of the fourth FET are mirror-symmetry with respect to the second gate cut region.

According to another embodiment, the structure further includes a conductive via formed inside the second gate cut region, where a source/drain (S/D) region of the first FET is conductively connected to a backside power rail by the conductive via, and the second gate cut region insulates the conductive via from the second FET and the fourth FET.

According to yet another embodiment, the structure further includes a conductive via formed inside the second gate cut region, where a source/drain (S/D) region of the second FET is conductively connected to a middle-of-line contact at a front side of the semiconductor structure, and the second gate cut region insulates the conductive via from the first FET and the third FET.

In another embodiment, the S/D region of the fourth FET is connected to a middle-of-line contact through a deep-via.

In one embodiment, the S/D region of the second FET is connected to a backside power rail through a backside contact.

In another embodiment, the first FET and the second FET are a first and a second nanosheet transistor having a first set of nanosheets and a second set of nanosheets respectively, and where a width of the first set of nanosheets is narrower than a width of the second set of nanosheets. The narrower width of the first set of nanosheets, and so associated narrower S/D region of the first nanosheet transistor, enables frontside access to the S/D region of the second nanosheet transistor.

According to one embodiment, where the cell unit is a first cell unit, the structure further includes a second cell unit, the second cell unit including a third FET stacked on top of a fourth FET; and a third cell boundary made of a third gate cut region with a third width; and a fourth cell boundary made of the first gate cut region with the first width, where the third width of the third gate cut region is substantially same as the first width of the first gate cut region, and where the first cell unit has a cell height that is smaller than a cell height of the second cell unit. Here, two different cell units may be formed to share a cell boundary of a first type of gate cut region of a narrow width.

According to another embodiment, where the cell unit is a first cell unit, the structure further includes a second cell unit, the second cell unit including a third FET stacked on top of a fourth FET; and a third cell boundary made of the second gate cut region with the second width; and a fourth cell boundary made of a third gate cut region with a third width, where the third width of the third gate cut region is substantially same as the second width of the second gate cut region and is wider than the first width of the first gate cut region, and where the first cell unit has a cell height that is larger than a cell height of the second cell unit. Here, two different cell units may be formed to share a cell boundary of a second type of gate cut region of a wide width.

Embodiments of present invention also provide a method of forming a semiconductor structure. The method includes forming multiple stacks of nanosheets on top of a substrate and a gate structure on top of and surrounding the multiple stacks of nanosheets; cutting the gate structure to create at least a first gate cut opening and a second gate cut opening, and dividing the multiple stacks of nanosheets into at least a first stack of nanosheets between the first gate cut opening and the second gate cut opening, wherein the first stack of nanosheets includes a first set of nanosheets of a first transistor on top of a second set of nanosheets of a second transistor, and wherein the first gate cut opening has a first width and the second gate cut opening has a second width with the second width being larger than the first width; forming a first gate cut region by depositing a dielectric material to fully fill the first gate cut opening; forming liners lining sidewalls of the second gate cut opening with the dielectric material; and forming a second gate cut region by filling the second gate cut opening between the liners with a conductive material, the conductive material forming a conductive via.

In one embodiment, cutting the gate structure further includes creating a third gate cut opening and dividing the multiple stacks of nanosheets into a second stack of nanosheets between the second gate cut opening and the third gate cut opening, wherein the second stack of nanosheets includes a third set of nanosheets of a third transistor on top of a fourth set of nanosheets of a fourth transistor, and wherein the third gate cut opening has a third width that is substantially same as the first width of the first gate cut opening; and forming a third gate cut region by depositing the dielectric material to fully fill the third gate cut opening.

### BRIEF DESCRIPTION OF THE DRAWINGS

The present invention will be understood and appreciated more fully from the following detailed description of embodiments of present invention, taken in conjunction with accompanying drawings of which:

FIGS. 1A and 1B to FIGS. 13A and 13B are demonstrative illustrations of cross-sectional views and FIG. 1C to FIG. 13C are simplified top views of a semiconductor structure at different steps of manufacturing thereof according to embodiments of present invention;

FIGS. 14A, 14B, and 14C are demonstrative illustrations of cross-sectional views of several cells having different cell heights according to embodiments of present invention;

FIG. 15 is a demonstrative illustration of cross-sectional view of a semiconductor structure having a first combination of cells according to one embodiment of present invention;

FIG. 16 is a demonstrative illustration of cross-sectional view of a semiconductor structure having a second combination of cells according to another embodiment of present invention; and

FIG. 17 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

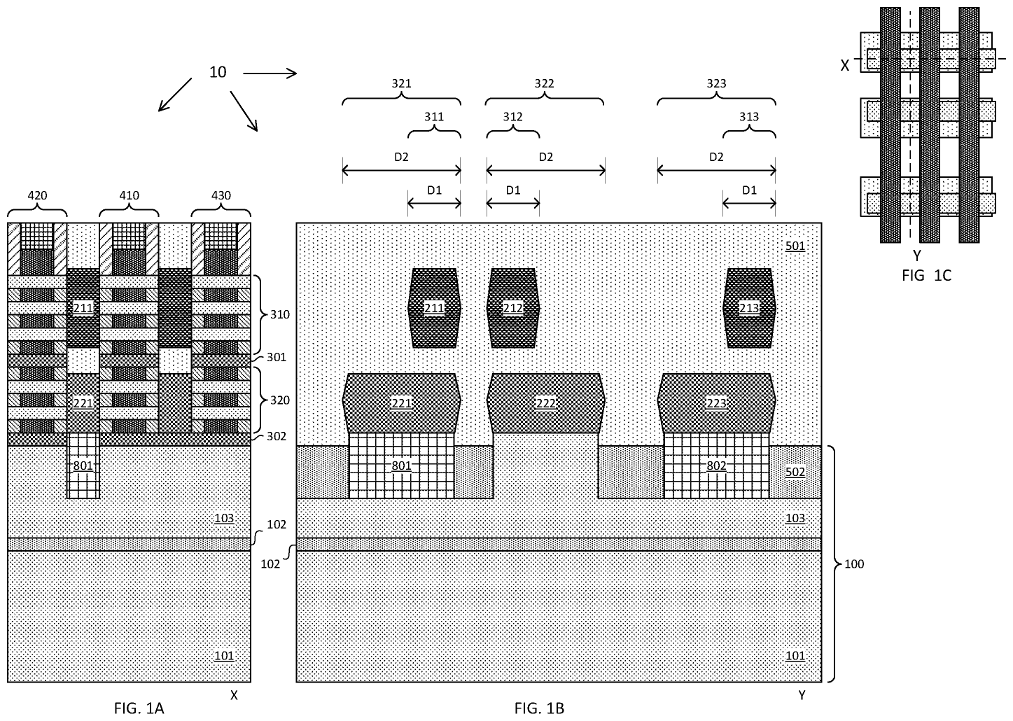

FIGS. 1A and 1B are demonstrative illustrations of different cross-sectional views and FIG. 1C is a simplified top view of a semiconductor structure in a step of manufacturing thereof according to one embodiment of present invention. More specifically, FIG. 1A illustrates a cross-sectional view of the semiconductor structure along a dashed line X as is illustrated in FIG. 1C. In other words, the cross-sectional view in FIG. 1A is made across a gate in a direction along the length of the gate. FIG. 1B illustrates a cross-sectional view of the semiconductor structure along a dashed line Y as is illustrated in FIG. 1C. In other words, the cross-sectional view in FIG. 1B is made across a S/D region in a direction along the width of the gate. Since its purpose is to illustrate locations of the cross-sections shown in FIGS. 1A and 1B, FIG. 1C may only selectively illustrate key elements such as, for example, nanosheets, gates, and S/D regions that are formed, yet to be formed, and sometimes whose views may be blocked. Elements such as dielectric cap layer, sidewall spacers, and other features may not necessarily be illustrated in order not to overcrowd FIG. 1C, and to the extent that their omission from FIG. 1C does not hinder the description of embodiments of present invention, which are mainly provided hereinafter with reference to FIG. 1A and FIG. 1B.

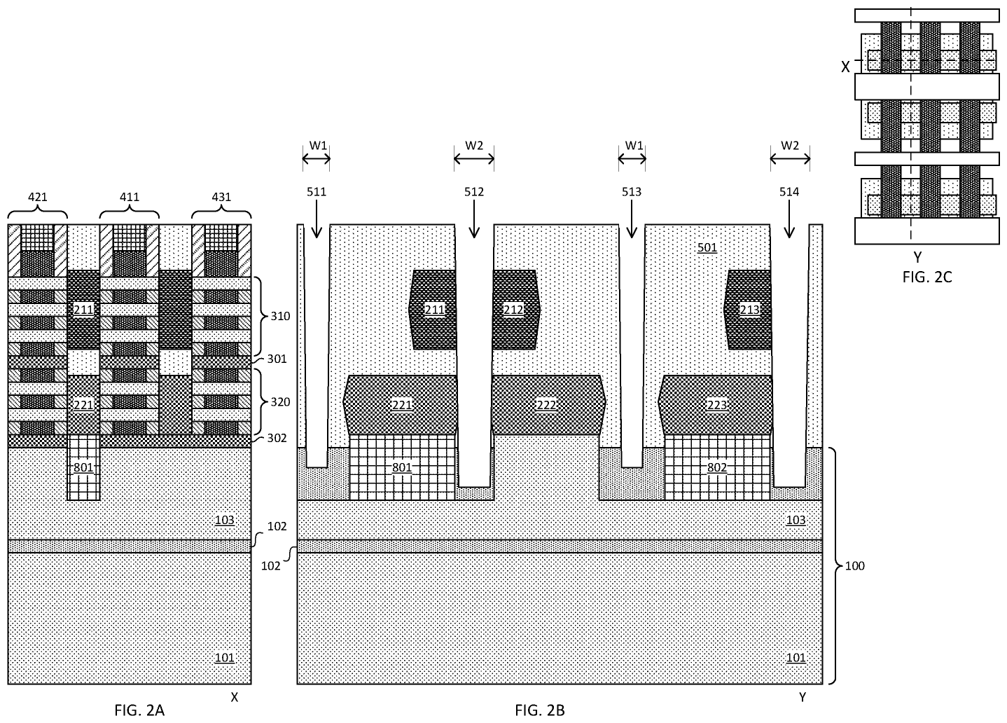

Likewise, FIGS. 2A and 2B to FIGS. 13A and 13B are demonstrative cross-sectional views and FIG. 2C to FIG. 13C are simplified top views of the semiconductor structure, at different manufacturing steps, illustrated in manners similar to FIGS. 1A, 1B, and 1C respectively.

Embodiments of present invention provide a method of forming a semiconductor structure 10. As is illustrated in FIGS. 1A, 1B, and 1C, the method includes receiving or providing a semiconductor substrate 100 and forming multiple sets of nanosheet transistors on top of the semiconductor substrate 100. However, it is to be noted here that embodiments of present invention are not limited in this aspect and may be applied to other types of transistors and/or active devices. The semiconductor substrate 100 may include a bulk silicon (Si) substrate 101; an etch-stop layer 102 such as a silicon-germanium (SiGe) layer on top of the Si substrate 101; and a Si layer 103 on top of the etch-stop layer 102. In one embodiment, the semiconductor substrate 100 may be a silicon-on-insulator (SOI) layer where the etch-stop layer 102 may be a dielectric layer.

In forming the multiple sets of nanosheet transistors, embodiments of present invention provide forming multiple stacks of nanosheets, such as a first multiple sets of nanosheets 310 and a second multiple sets of nanosheets 320, on top of the substrate 100. More particularly, the second multiple sets of nanosheets 320 may be formed on top of and separated from the substrate 100 by a bottom dielectric insulator (BDI) 302, and the first multiple sets of nanosheets 310 may be formed on top of and separated from the second multiple sets of nanosheets 320 by a middle dielectric insulator (MDI) 301.

Embodiments of present invention further provide epitaxially forming multiple source/drain (S/D) regions between the first multiple sets of nanosheets 310, and between the second multiple sets of nanosheets 320. In other words, multiple S/D regions may be formed at the ends of the first multiple sets of nanosheets 310 and at the ends of the second multiple sets of nanosheets 320 to form multiple sets of nanosheet transistors as being described below in more details.

For example, a first set of nanosheet transistors may be formed to include a first nanosheet transistor 311 on top of a second nanosheet transistor 321. The first nanosheet transistor 311 may include a first S/D region 211 formed at an end of one of the first multiple sets of nanosheets 310 and the second nanosheet transistor 321 may include a second S/D region 221 formed at an end of one of the second multiple sets of nanosheets 320. The first S/D region 211 may be epitaxially formed to have a width D1 corresponding to a width of the first multiple sets of nanosheets 310. In other words, the first multiple sets of nanosheets 310 may have a width equal to or slightly less than D1. The second S/D region 221 may be epitaxially formed to have a width D2 corresponding to a width of the second multiple sets of nanosheets 320. In other words, the second multiple sets of nanosheets 320 may have a width equal to or slightly less than D2. The first S/D region 211 may be formed to align with one side, such as the right side as is illustrated in FIG. 1B, of the second S/D region 221 such that a portion, such as a left portion, of the second S/D region 221 may not be vertically covered or blocked by the first S/D region 211 and access to the second S/D region 221 is available from the top thereof.

Similarly, embodiments of present invention may form a second set of nanosheet transistors that may include a third nanosheet transistor 312 on top of a fourth nanosheet transistor 322. The third nanosheet transistor 312 may include a third S/D region 212 formed at an end of one of the first multiple sets of nanosheets 310 and the fourth nanosheet transistor 322 may include a fourth S/D region 222 formed at an end of one of the second multiple sets of nanosheets 320. The third S/D region 212 may be epitaxially formed to have a width D1 corresponding to the width of the first multiple sets of nanosheets 310 that is equal to or slightly less than D1. The fourth S/D region 222 may be epitaxially formed to have a width D2 corresponding to the width of the second multiple sets of nanosheets 320 that is equal to or slightly less than D2. The third S/D region 212 may be formed to align with one side, such as the left side as is illustrated in FIG. 1B, of the fourth S/D region 222 such that a portion, such as a right portion, of the fourth S/D region 222 may not be vertically covered or blocked by the third S/D region 212 and access to the fourth S/D region 222 is available from the top thereof.

One or more sets of nanosheet transistors may be formed in manners similar to the above. For example, a third set of nanosheet transistors may be formed to include a fifth nanosheet transistor 313 on top of a sixth nanosheet transistor 323. The fifth nanosheet transistor 313 may include a fifth S/D region 213 formed at an end of one of the first multiple sets of nanosheets 310 and the sixth nanosheet transistor 323 may include a sixth S/D region 223 formed at an end of one of the second multiple sets of nanosheets 320. The fifth S/D region 213 may be epitaxially formed to have a width D1 corresponding to the width of the first multiple sets of nanosheets 310 that is equal to or slightly less than D1. The sixth S/D region 223 may be epitaxially formed to have a width D2 corresponding to the width of the second multiple sets of nanosheets 320 that is equal to or slightly less than D2. The fifth S/D region 213 may be formed to align with one side, such as the right side as in FIG. 1B, of the sixth S/D region 223 such that a portion, such as a left portion, of the sixth S/D region 223 may not be vertically covered or blocked by the fifth S/D region 213.

In one embodiment, before forming the S/D regions such as the second, the fourth, and the sixth S/D region 221, 222, and 223, a shallow-trench-isolation (STI) 502 may be formed in parts of the Si layer 103. Subsequently, openings may be created in the STI 502 to expose the underneath Si layer 103, and one or more placeholders may be formed in the openings directly from the Si layer 103. For example, silicon-germanium (SiGe) may be epitaxially grown in the openings created in the STI 502, directly from the Si layer 103, to form a first placeholder 801 and a second placeholder 802. The placeholders, such as the first and the second placeholder 801 and 802, may be formed for the purpose of forming backside contacts later in process.

Embodiments of present invention further provide forming multiple gate structures on top of and surrounding the multiple stacks of nanosheets. For example, a gate structure 410 may be formed on top of and surrounding a plurality of the first multiple sets of nanosheets 310 that form the first, the third, and the fifth nanosheet transistor 311, 312, and 313, and surrounding a plurality of the second multiple sets of nanosheets 320 that form the second, the fourth, and the sixth nanosheet transistor 321, 322, and 323. Additional gate structures such as gate structures 420 and 430 may be formed on top of and surrounding one or more of the first and the second multiple sets of nanosheets 310 and 320. One or more dielectric layers such as a dielectric layer 501 may be formed between the multiple gate structures 410, 420, and 430 and in-between the multiple S/D regions 211, 212, 213, 221, 222, and 223 thereby providing insulation thereof.

FIGS. 2A and 2B are demonstrative illustrations of different cross-sectional views and FIG. 2C is a simplified top view of a semiconductor structure in a step of manufacturing thereof according to one embodiment of present invention. More particularly, following the step illustrated in FIGS. 1A, 1B, and 1C, embodiments of present invention provide performing a gate cute procedure to cut the gate structures 410, 420, and 430 at one or more cell boundaries, thereby creating one or more gate cut openings at the cell boundaries. For example, a first gate cut opening 511 and a second gate cut opening 512 may be created in the dielectric layer 501 and partially into the STI 502, thereby dividing the multiple stacks of nanosheets into at least a first stack of nanosheets between the first and the second gate cut opening 511 and 512. The first stack of nanosheets may include a first set of nanosheets 310 for the first nanosheet transistor 311 and a second set of nanosheets 320 for the second nanosheet transistor 321 underneath the first nanosheet transistor 311.

The first gate cut opening 511 may have a first width W1, and the second gate cut opening 512 may have a second width W2 and the second width W2 may be larger than the first width W1. In one embodiment, the second width W2 may be wide enough to cut partially through the first and the third S/D regions 211 and 212 and partially through the second and the fourth S/D regions 221 and 222.

Embodiments of present invention may further provide cutting the gate structures to form a third gate cut opening 513 with a width W1 and a fourth gate cut opening 514 with a width W2, thereby dividing the multiple stacks of nanosheets further into a second stack of nanosheets and a third stack of nanosheets. The second stack of nanosheets may include a third set of nanosheets 310 and a fourth set of nanosheets 320 between the second gate cut opening 512 and the third gate cut opening 513, and the fourth stack of nanosheets may include a fifth set of nanosheets 310 and a sixth set of nanosheets 320 between the third gate cut opening 513 and the fourth gate cut opening 514.

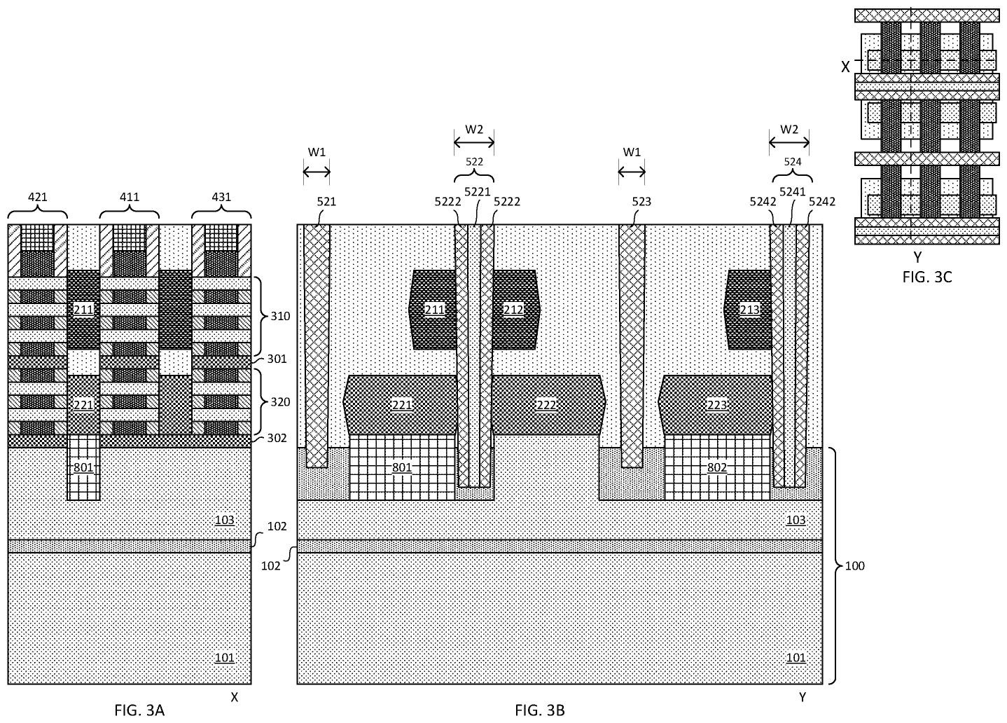

FIGS. 3A and 3B are demonstrative illustrations of different cross-sectional views and FIG. 3C is a simplified top view of a semiconductor structure in a step of manufacturing thereof according to one embodiment of present invention. More particularly, following the step illustrated in FIGS. 2A, 2B, and 2C, embodiments of present invention provide filling the first and the third gate cut openings 511 and 513 with a first dielectric material to form a first and a third gate cut regions 521 and 523, and filling the second and the fourth gate cut openings 512 and 514 with both the first dielectric material and a second dielectric material, or a conductive material, to form a second and a fourth gate cut regions 522 and 524.

For example, a conformal layer of first dielectric material may be formed through, for example, an atomic layer deposition (ALD) process to line sidewalls of the first, second, third, and fourth gate cut openings 511, 512, 513, and 514. The conformal layer of first dielectric material may pinch off in the gate cut openings with a narrow width W1 to fully fill the first and the third gate cut openings 511 and 513 to become a first and a third gate cut regions 521 and 523. In the meantime, the conformal layer of first dielectric material may line the second gate cut opening 512 to form a liner 5222 and line the fourth gate cut opening 514 to form a liner 5242. Both the second and the fourth gate cut openings 512 and 514 have a wide width W2 that is wider than twice the thickness of the conformal layer of first dielectric material. Therefore, the conformal layer of first dielectric material may not pinch inside the second and the fourth gate cut openings 512 and 514.

Following the deposition of the conformal layer of first dielectric material, a portion of the liner 5222 and liner 5242 at the bottom of the second and the fourth gate cut openings 512 and 514 may be selectively removed in a directional etch process such as, for example, a reactive-ion-etch (RIE) process. A second dielectric material or other suitable insulating material may then be used to fill a gap between the liners 5222 in the second gate cut opening 512 to form a dielectric filler 5221. The dielectric filler 5221, together with the liners 5222, form a second gate cut region 522. Similarly, the second dielectric material or insulating material may fill a gap between the liners 5242 in the fourth gate cut opening 514 to form a dielectric filler 5241. The dielectric filler 5241, together with the liners 5242, form a fourth gate cut region 524. Here, it is noted that the second dielectric material or insulating material may be different from the first dielectric material in properties such as they may have different etch selectivity so that the second dielectric material may be selectively etched away from the first dielectric material as being described below in more details.

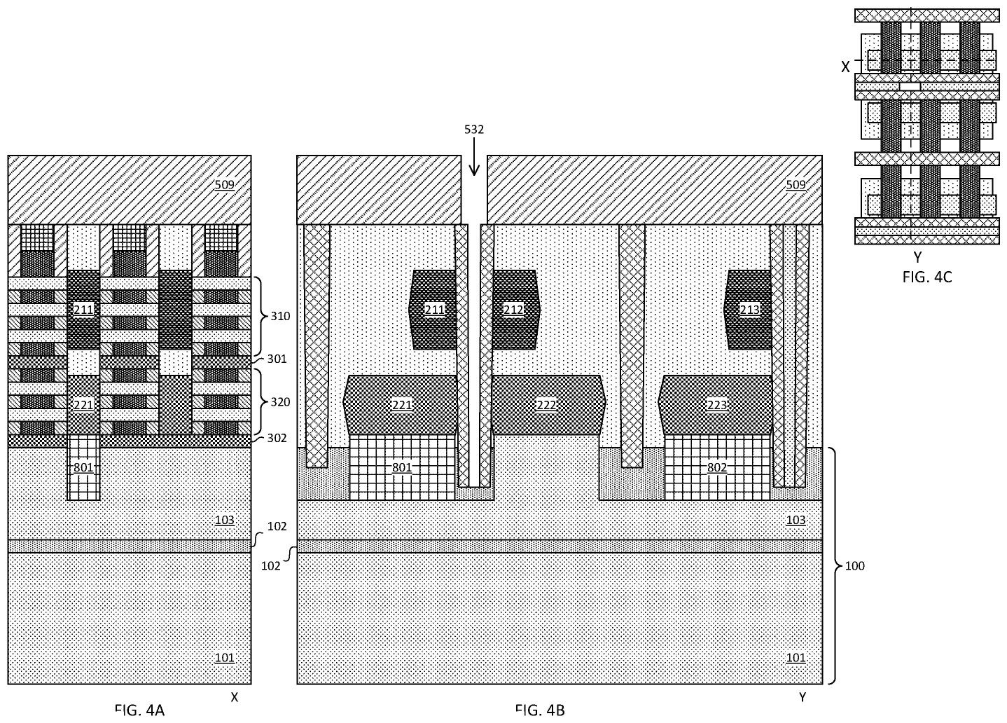

FIGS. 4A and 4B are demonstrative illustrations of different cross-sectional views and FIG. 4C is a simplified top view of a semiconductor structure in a step of manufacturing thereof according to one embodiment of present invention. More particularly, following the step illustrated in FIGS. 3A, 3B, and 3C, embodiments of present invention provide forming a mask 509 over the semiconductor structure 10 with the mask 509 exposing one or more of the gate cut regions where forming conductive via or vias may be desired or planned. In particular, the exposed one or more gate cut regions may be gate cut regions with the wide width W2 such as, for example, the second gate cut region 522 and the dielectric filler 5221 of the second gate cut region 522 may be exposed. Here, the mask 509 may be an organic planarization layer (OPL).

Following the formation of the mask 509, a selective etch process may be applied to selectively remove the exposed dielectric filler 5221, thereby creating an opening 532 within the second gate cut region 522 that is surrounded by the liner 5222 of first dielectric material.

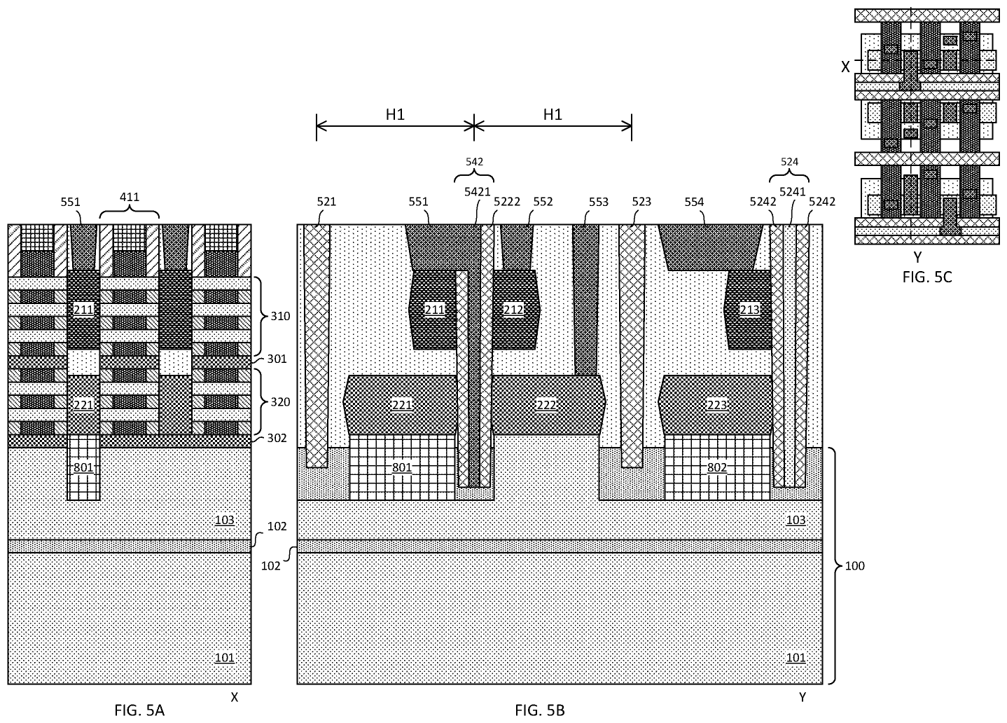

FIGS. 5A and 5B are demonstrative illustrations of different cross-sectional views and FIG. 5C is a simplified top view of a semiconductor structure in a step of manufacturing thereof according to one embodiment of present invention. More particularly, following the step illustrated in FIGS. 4A, 4B, and 4C, embodiments of present invention provide removing the mask 509 and filling the opening 532 with a conductive material to form a conductive via 5421 that is insulated from the surroundings such as, for example, the first and the third S/D region 211 and 212 and the second and the fourth S/D region 221 and 222, by the liners 5222. As is illustrated in FIG. 5B, the conductive via 5421 may extend from a level above a top surface of the first and the third S/D region 211 and 212 to a level below a bottom surface of the second and the fourth S/D region 221 and 222. The conductive via 5421 together with the surrounding liners 5222 form a new second gate cut region 542. It is to be noted here that the fourth gate cut region 524 remains formed from the first and the second dielectric materials to include to no conductive via.

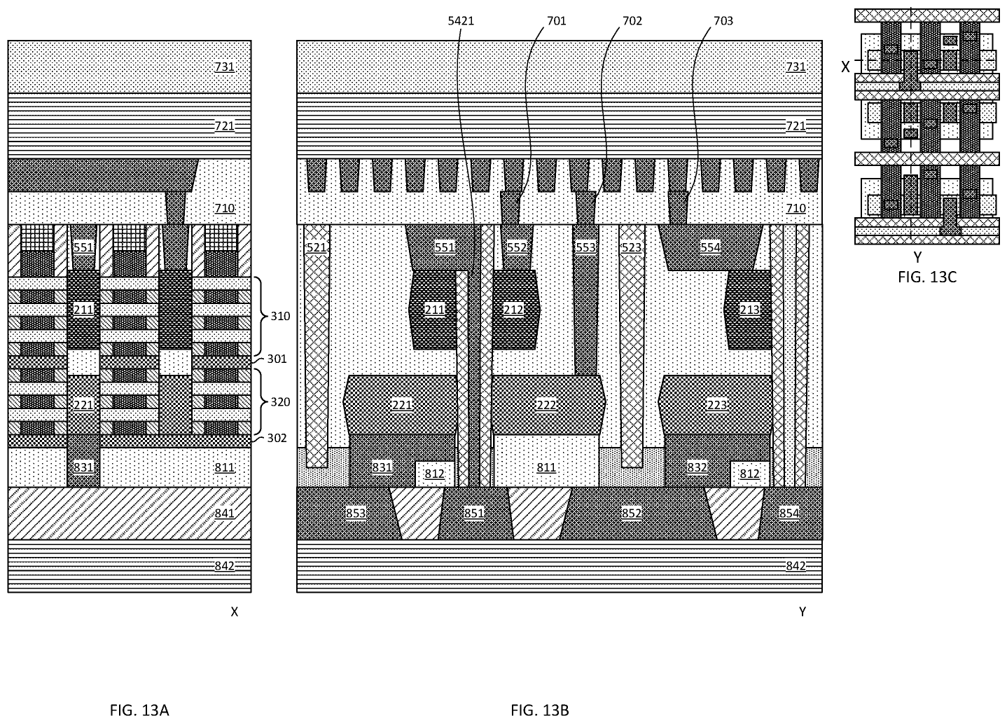

Embodiments of present invention further provide patterning the dielectric layer 501 and/or the gate cut regions 521, 542, 523 and 524 to create one or more openings; lining the one or more openings with a silicide liner such as titanium (Ti), nickel (Ni), or nickel-platinum (NiPt); and filling the one or more openings, on top of the silicide liner, with conductive material, such as aluminum (Al), tungsten (W), and/or ruthenium (Ru), to form one or more S/D contacts. For example, a first S/D contact 551 may be formed to be in contact with the first S/D region 211 as well as in contact with the conductive via 5421. Thereby, the first S/D region 211 of the first nanosheet transistor 311 at the top of the set of nanosheet transistors may be made in contact with a backside power rail (BSPR) 851, via the conductive via 5421, as being described below in more details with reference to FIGS. 13A and 13B.

Similar to the first S/D contact 551, a second S/D contact 552 may be formed to be in contact with the third S/D region 212 of the third nanosheet transistor 312 at the top; a third S/D contact 553 may be formed, through the form of a deep-via, to be in contact with the fourth S/D region 222 of the fourth nanosheet transistor 322 at the bottom; and a fourth S/D contact 554 may be formed to be in contact with the fifth S/D region 213 of the fifth nanosheet transistor 313 at the top. In other words, S/D contacts may be made from the frontside of the semiconductor structure 10 to be in contact with S/D regions of the various sets of nanosheet transistors either at the top or at the bottom of the sets.

According to one embodiment, the first set of nanosheet transistors that includes the first and the second nanosheet transistor 311 and 321 (see FIG. 1B) forms a first cell, or cell unit, with a cell height H1. The first cell has a first cell boundary at the first gate cut region 521 and the second cell boundary at the second gate cut region 542. The second set of nanosheet transistors that includes the third and the fourth nanosheet transistor 312 and 322 forms a second cell, or cell unit, with a same cell height H1. The second cell has a first cell boundary at the second gate cut region 542 and a second cell boundary at the third gate cut region 523. The first cell and the second cell are mirror-symmetry with respect to the second gate cut region 542. In other words, the first S/D region 211 and the third S/D region 212 are mirror-symmetry and the second S/D region 221 and the fourth S/D region 222 are mirror-symmetry as well, all with respect to the second gate cut region 542. Additionally, the third set of nanosheet transistors that includes the fifth nanosheet transistor 313 and the sixth nanosheet transistor 323 forms a third cell with a same cell height H1. The second and the third cell may be mirror-symmetry with respect to the third gate cut region 523. Hereinafter, the terms “cell” and “cell unit” may be used interchangeably.

Hereinafter, the above first, second, and third cells may be referred to as a first type of cell. As is discussed above and according to embodiments of present invention, when two of the first type of cells are formed next to each other, they are formed in mirror-symmetry form with respect to either a first type or a second type of gate cut region. The first type of gate cut region is a gate cut region with a narrow width W1 and the second type of gate cut region is a gate cut region with a wide width W2 as being described above. If needed, the second type of gate cut region may be formed to include a conductive via there-within that may provide a conductive path for the S/D regions directly next to the second type of gate cut region.

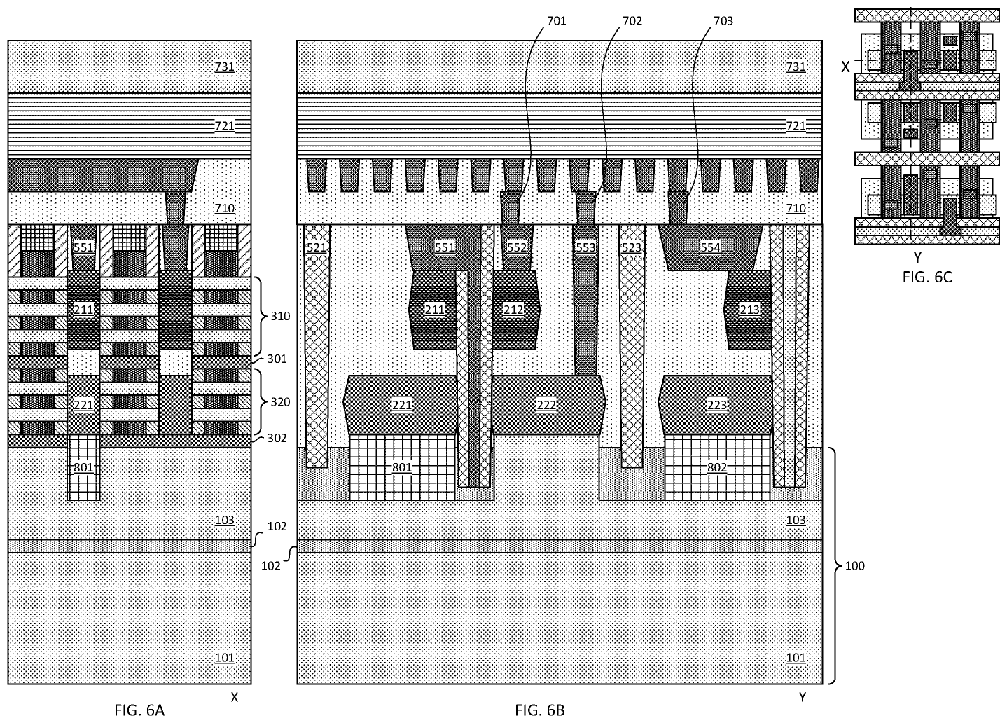

FIGS. 6A and 6B are demonstrative illustrations of different cross-sectional views and FIG. 6C is a simplified top view of a semiconductor structure in a step of manufacturing thereof according to one embodiment of present invention. More particularly, following the step illustrated in FIGS. 5A, 5B, and 5C, embodiments of present invention provide forming an interlevel dielectric (ILD) layer 710 on top of the dielectric layer 501, the S/D contacts 551, 552, 553, and 554, and the gate cut regions 521, 542, 523, and 524. One or more middle-of-line (MOL) contacts, such as MOL contacts 701, 702, and 703 may be formed in the ILD layer 710 to be in contact with one or more S/D contacts such as the second S/D contact 552, the third S/D contact 553, and the fourth S/D contact 554.

Moreover, a back-end-of-line (BEOL) structure 721 may be formed on top of the ILD layer 710 to provide signal routing and/or power supply to the various sets of nanosheet transistors. A carrier wafer 731 may bonded onto the BEOL structure 721 such that the semiconductor structure 10 may be flipped upside-down for further processing from the backside of the semiconductor substrate 100.

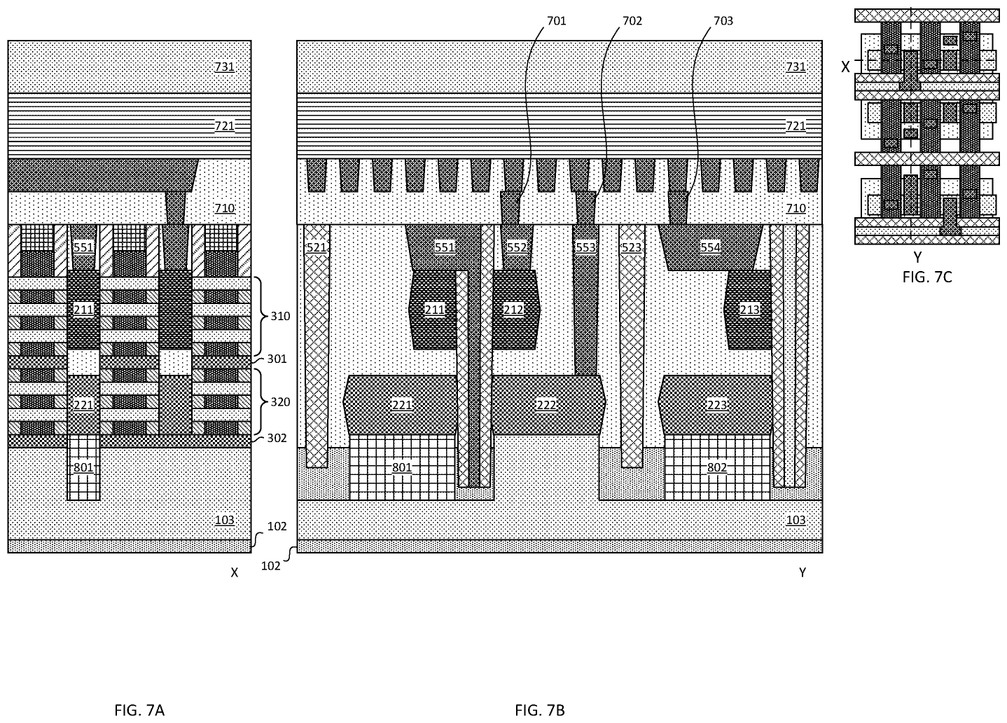

It is to be noted here that upside-up (instead of upside-down) drawings will continue to be used hereinafter for FIGS. 7A and 7B to FIGS. 13A and 13B, for the ease of illustration. However, description of the drawings may be provided in a manner that is consistent with a situation where the semiconductor structure 10 is flipped upside-down and being processed from the backside of the semiconductor substrate 100.

FIGS. 7A and 7B are demonstrative illustrations of different cross-sectional views and FIG. 7C is a simplified top view of a semiconductor structure in a step of manufacturing thereof according to one embodiment of present invention. More particularly, following the step illustrated in FIGS. 6A, 6B, and 6C, embodiments of present invention provide removing, such as through a combination of wafer grinding, CMP, dry and wet etch process, the Si substrate 101. For better process control, the removing process of the Si substrate 101 may stop at the etch-stop layer 102.

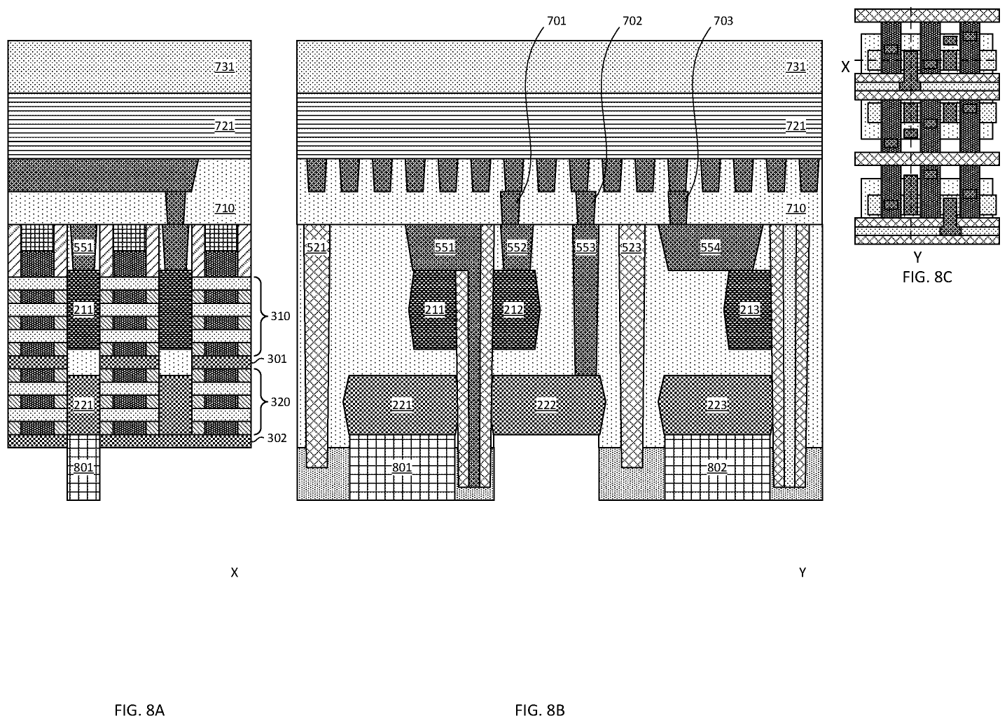

FIGS. 8A and 8B are demonstrative illustrations of different cross-sectional views and FIG. 8C is a simplified top view of a semiconductor structure in a step of manufacturing thereof according to one embodiment of present invention. More particularly, following the step illustrated in FIGS. 7A, 7B, and 7C, embodiments of present invention provide continuing to remove the etch-stop layer 102 to expose the Si layer 103, and removing the exposed Si layer 103 in a selective etch process. The selective etch process may therefore expose the placeholders such as the first and the second placeholders 801 and 802, the STI 502 that surrounds the placeholders 801 and 802, and BDI 302, and may also expose bottom surfaces of one or more S/D regions of the nanosheet transistors at the bottom such as the fourth S/D region 222 of the fourth nanosheet transistor 322 of the second set of nanosheet transistors.

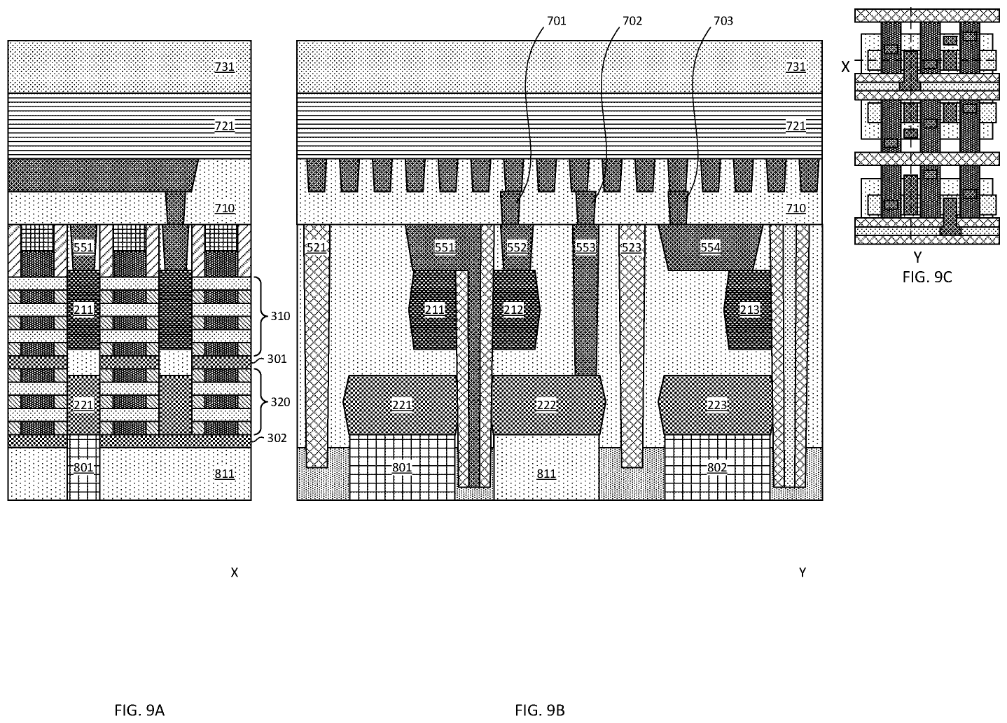

FIGS. 9A and 9B are demonstrative illustrations of different cross-sectional views and FIG. 9C is a simplified top view of a semiconductor structure in a step of manufacturing thereof according to one embodiment of present invention. More particularly, following the step illustrated in FIGS. 8A, 8B, and 8C, embodiments of present invention provide forming a backside interlevel dielectric (BILD) layer 811 on top of the exposed bottom surface of the S/D region 222, the BDI 302, and the placeholders 801 and 802 and the STI 502. A CMP process may subsequently be applied to planarize a top surface of the BILD layer 811 until at least the placeholders 801 and 802 are exposed.

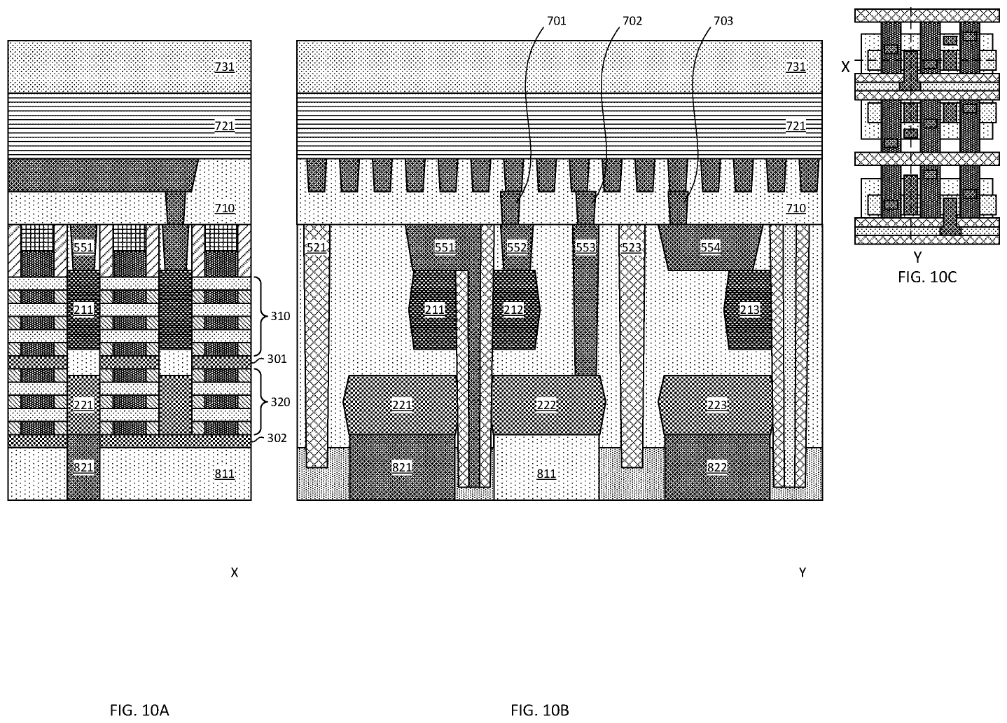

FIGS. 10A and 10B are demonstrative illustrations of different cross-sectional views and FIG. 10C is a simplified top view of a semiconductor structure in a step of manufacturing thereof according to one embodiment of present invention. More particularly, following the step illustrated in FIGS. 9A, 9B, and 9C, embodiments of present invention provide selectively removing the placeholders 801 and 802, in a selective etch process that is selective to the surrounding STI 502; lining the openings created by the removal of the placeholders 801 and 802 with a silicide liner such as, for example, Ti, Ni, NiPt, and/or other suitable materials; and filling the openings on top of the silicide liner with a conductive material such as Al, W, and/or Ru to form backside contacts (BCA). For example, a first BCA 821 may be formed to be in contact with a bottom surface of the second S/D region 221 of the second nanosheet transistor 321 of the first set of nanosheet transistors. Also for example, a second BCA 822 may be formed to be in contact with a bottom surface of the sixth S/D region 223 of the sixth nanosheet transistor 323 of the third set of nanosheet transistors. In other words, backside contacts may be formed to contact S/D regions of the one or more nanosheet transistors at the bottom of the various sets of nanosheet transistors.

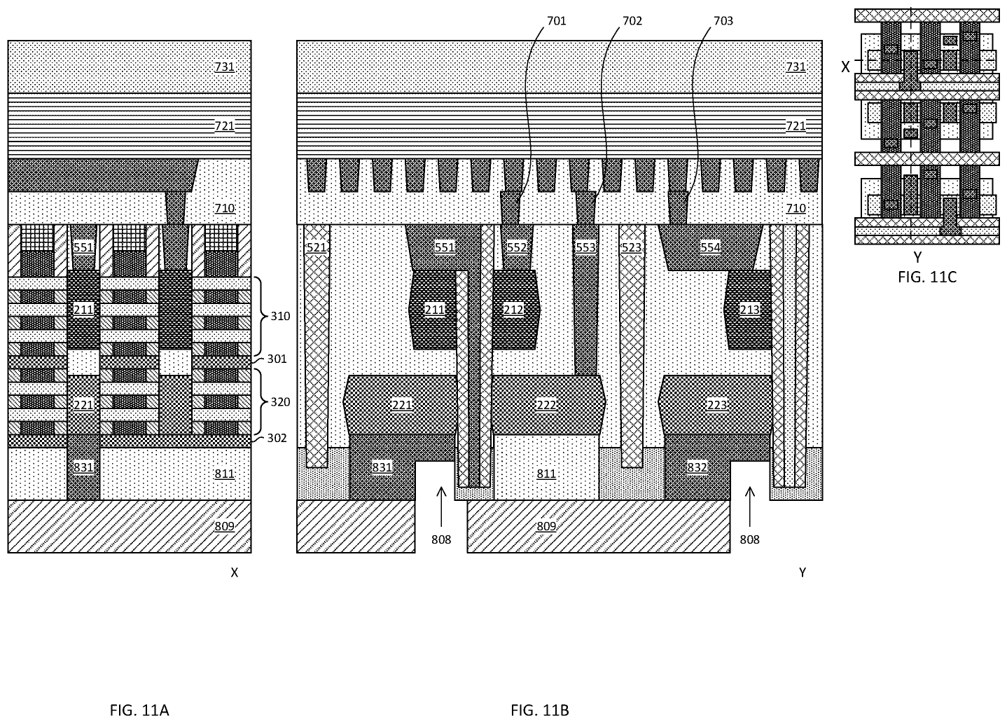

FIGS. 11A and 11B are demonstrative illustrations of different cross-sectional views and FIG. 11C is a simplified top view of a semiconductor structure in a step of manufacturing thereof according to one embodiment of present invention. More particularly, following the step illustrated in FIGS. 10A, 10B, and 10C, embodiments of present invention provide patterning the backside contacts, such as the first BCA 821 and the second BCA 822, so that they are not in direct contact with, and thus may be insulated from, the bottom surface of the gate cut regions, in particular the second gate cut regions 542 and the fourth gate cut regions 524 that have the wide width W2 and may include a conductive via therewithin. For example, a mask 809 may be created and the mask 809 may include one or more openings that expose the underneath backside contacts, such as the first and the second BCA 831 and 832, in areas near the second gate cut region 542 and the fourth gate cut region 524. Next, a selective etch process may be applied to create openings 808, by removing portions of the first BCA 831 and the second BCA 832, such that the first BCA 831 and the second BCA 832 near the gate cut regions 542 and 524, if still exists, may be sufficiently below the top surfaces of the gate cut regions 542 and 524.

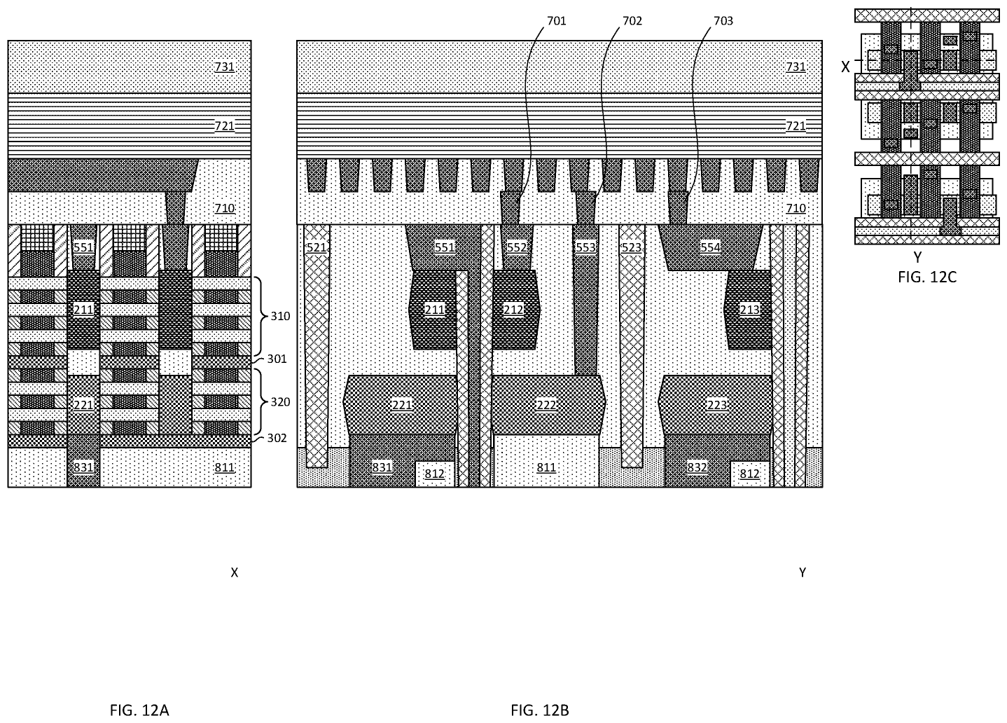

FIGS. 12A and 12B are demonstrative illustrations of different cross-sectional views and FIG. 12C is a simplified top view of a semiconductor structure in a step of manufacturing thereof according to one embodiment of present invention. More particularly, following the step illustrated in FIGS. 11A, 11B, and 11C, embodiments of present invention provide filling the openings 808 with a dielectric material, for example, to form a dielectric layer 812. A CMP process may subsequently be applied to planarize the dielectric layer and to expose the top surface of the gate cut regions 542 and 524, in particular the top surface of the second gate cut region 542 such that the conductive via 5421 therein may be exposed.

FIGS. 13A and 13B are demonstrative illustrations of different cross-sectional views and FIG. 13C is a simplified top view of a semiconductor structure in a step of manufacturing thereof according to one embodiment of present invention. More particularly, following the step illustrated in FIGS. 12A, 12B, and 12C, embodiments of present invention provide forming a BILD layer 841 on top of the exposed first and the exposed second BCA 831 and 832, on top of the BILD layer 811, and on top of the dielectric layer 812. One or more openings may be created in the BILD layer 841 to expose top surfaces of the first BCA 831 and the second BCA 832, and the top surfaces of the second gate cut region 542 and the fourth gate cut region 524. Conductive material may be deposited into the one or more openings to form one or more backside power rails such as the first, the second, the third, and the fourth backside power rail (BSPR) 851, 852, 853, and 854. More particularly, the first BSPR 851 may be in contact with the conductive via 5421 thereby in contact with the first S/D region 211 of the first nanosheet transistor 311.

The second BSPR 852 may be in contact with the second BCA 832 thereby in contact with the fourth S/D region of the fourth nanosheet transistor 322. The third BSPR 853 may be in contact with the first BCA 831 thereby in contact with the second S/D region 221 of the second nanosheet transistor 321. A backside power distribution network (BSPDN) 842 may subsequently be formed on top of the BILD layer 841 and the first, the second, the third, and the fourth BSPR 851, 852, 853, and 854.

It is to be noted here that, although not explicitly illustrated here, the second S/D region 221 of the second nanosheet transistor 321 at the bottom of the set of nanosheet transistors may be made in contact with a MOL contact, which may be formed if needed like the MOL contact 701, 702, or 703, at the frontside of the semiconductor structure 10 via the conductive via 5421 as well. It is understood that such connection is only available when the conductive via 5421 is not used by the first S/D region 211, not used by the third S/D region 212, and neither by the fourth S/D region 222. In other words, the conductive via 5421 is shared by the four S/D regions 211, 212, 221, and 222 with each S/D region having an equivalent 25% accessibility to the conductive via 5421. In some other design, the conductive via 5421 may be shared only by the first S/D region 211 and the third S/D region 212 at the top. In that case, the first and the third S/D region 211 and 212 each has an equivalent 50% accessibility to the conductive via 5421 while the second and the fourth S/D region 221 and 222 have 0% or no accessibility to the conductive via 5421. Here, we use a factor to define S/D accessibility in a cell, with a full access as a factor 1 and partial access as a fraction of 1. For example, 25% accessibility is given a factor 0.25. Embodiments of present invention provide three types of cell or cell unit designs and we compare accessibility factors and their associated cell heights of these cell unit designs below in more details.

As is discussed above with reference to FIGS. 5A and 5B, the first nanosheet transistor 311 (whose S/D region includes the first S/D region 211) and the second nanosheet transistor 321 (whose S/D region includes the second S/D region 221) form a cell of a first type. As far as accessibility to the S/D regions of the first type of cell is concerned, the first S/D region 211 has full (factor 1) direct access to the top and partial (factor 0.25) access to the bottom, via the conductive via 5421. The second S/D region 221 has more than full access to the top, via either the dielectric layer 501 (factor 1) or via the conductive via 5421 (factor 0.25), and full (factor 1) direct access to the bottom. In other words, embodiments of present invention provide a first type of cell that has a total factor of 3.5 of accessibility to the S/D regions in the cell. In the meantime, this first type of cell has a cell height H1 that is primarily determined by the width of the set of nanosheets at the bottom plus half of the first width W1 and half of the second width W2.

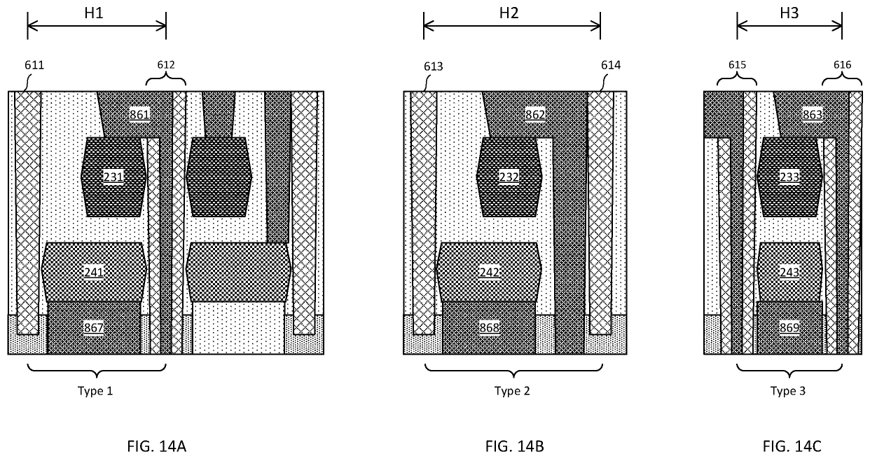

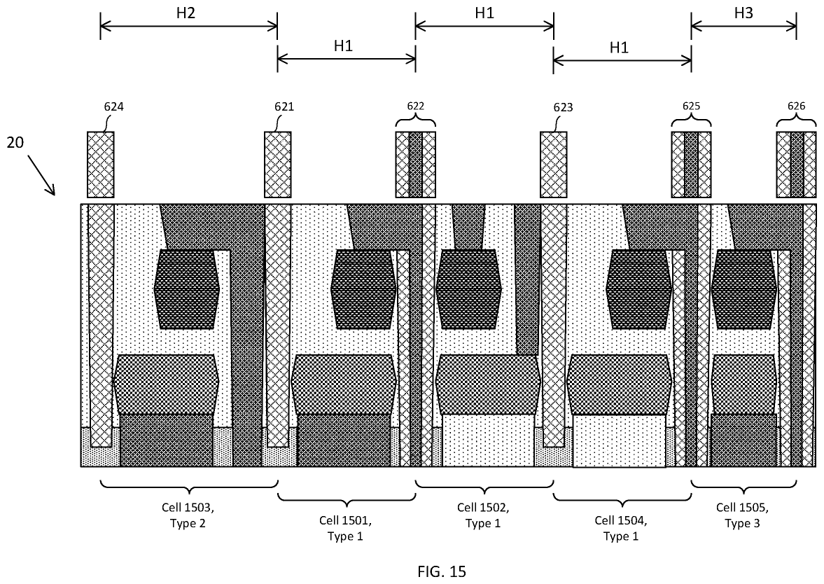

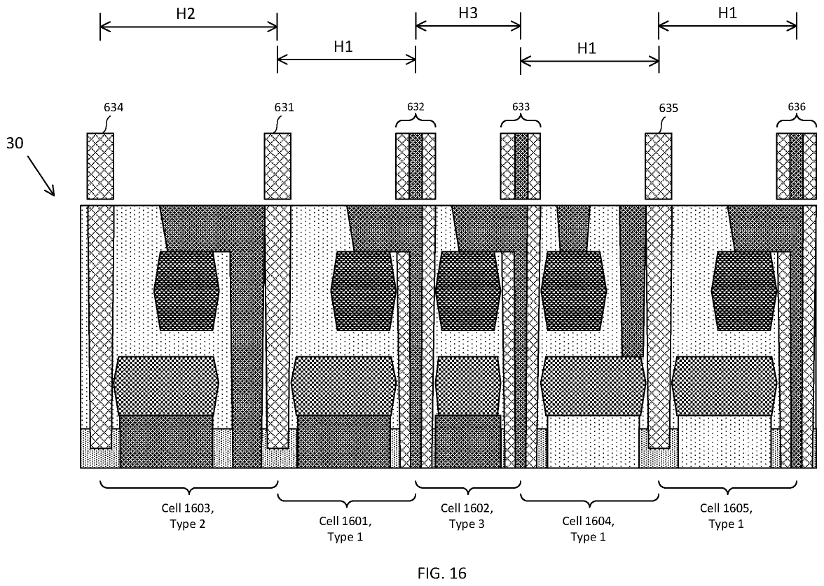

Hereinafter, embodiments of present invention further provide a second type of cell and a third type of cell in FIGS. 14B and 14C, with details of their accessibility and height and their comparison with the above first type of cell. Furthermore, use cases or combination of use cases of the three types of cells are also provided in FIGS. 15 and 16.

FIGS. 14A, 14B, and 14C are demonstrative illustrations of cross-sectional views of several cells or cell units having different cell heights according to embodiments of present invention. More particularly, FIG. 14A illustrates the first type of cell or cell unit as being described above. The first type of cell or cell unit has a first type of boundary 611 and a second type of boundary 612 and an accessibility factor 3.5 to access the S/D region 231 and 241 through, for example, contacts 861 and 867. The first type of cell or cell unit has a cell height H1 primarily determined by the width of set of nanosheets at the bottom and half the widths of the first and the second type of boundary (W1/2+W2/2), which are the first and the second type of gate cut region.

FIG. 14B demonstratively illustrates a second type of cell or cell unit between a first type of boundary 613 and a first type of boundary 614. Access to a top S/D region 232 may be made directly from the top (factor 1) or via a dedicated (factor 1) conductive via 862 from the bottom. Access to a bottom S/D region 242 may be made directly from the bottom contact 868 (factor 1) or through the dielectric layer from the top (factor 1). In other words, this second type of cell or cell unit has an accessibility factor of 4, larger than 3.5 of the first type of cell or cell unit. However, this second type of cell or cell unit has a cell height H2, which is determined by the width of the set of nanosheets at the bottom, one full width of the first type of boundary (W1), and additionally the space needed for forming the dedicated conductive via. Therefore, generally the cell height H2 of this second type of cell or cell unit is generally higher than the cell height H1 of the first type of cell or cell unit.

FIG. 14C demonstratively illustrates a third type of cell or cell unit between a second type of boundary 615 and a second type of boundary 616. Access to a top S/D region 233 may be made directly from the top (factor 1) or via a 50% shared conductive via 863 (factor 0.5) from the bottom. Access to a bottom S/D region 243 may be made directly from the bottom contact 869 (factor 1) or via the 50% shared conductive via 863 (factor 0.5). In other words, this third type of cell or cell unit has an accessibility factor of 3, smaller than 3.5 of the first type of cell or cell unit. However, this third type of cell or cell unit has a cell height H3, which is determined by the width of the set of nanosheets at the top (since the set of nanosheets at the bottom may have a same width as the one at the top) and one full width of the second type of boundary. Therefore, generally the cell height H3 of this third type of cell or cell unit is generally smaller than the cell height H1 of the first type of cell or cell unit.

Therefore, embodiments of present invention provide three types of cell unit designs. Among the three types of cell unit designs, the first type of cell unit has a S/D region accessibility that is larger or more flexible than the third type but smaller or less flexible than the second type, and a cell height that is smaller than the second type but larger than the third type. In other words, the second type of cell unit has the most flexibility in terms of S/D region accessibility but largest cell height. On the other hand, the third type of cell unit has the smallest cell height but least flexibility in terms of S/D region accessibility. The use or combination of use of these three types of cell units may depend on actual applications, two of which are demonstratively illustrated below.

FIG. 15 is a demonstrative illustration of cross-sectional view of a semiconductor structure having a first combination of cell units according to one embodiment of present invention. More particularly, embodiments of present invention provide a semiconductor structure 20 with multiple cell units separated either by a first type of boundary made of a first type of gate cut region 621, 623, or 624 of a first width W1 or by a second type of boundary made of a second type of gate cut region 622, 625, or 626 of a second width W2. The second type of the gate cut region 622, 625, or 626 may further each include a conductive via therein that provides a conductive path for connecting a top S/D region to a bottom backside power rail or a bottom S/D region to a middle-of-line contact at the frontside of the semiconductor structure 20.

For example, a cell unit 1501 of a first type may be next to a cell unit 1502 of a first type sharing a boundary of a second type of the gate cut region 622; a cell unit 1503 of a second type may be next to the cell unit 1501 of the first type sharing a boundary of a first type of the gate cut region 621; a cell unit 1504 of a first type may be next to the cell unit 1502 of the first type sharing a boundary of a first type of the gate cut region 623, and a cell unit 1505 of a third type may be next to the cell unit 1504 of the first type sharing a boundary of a second type of the gate cut region 625. Additionally, as is illustrated in FIG. 15, the cell unit 1503 of the second type may have a boundary of a first type of the gate cut region 624 shared with another cell to the left side thereof, and the cell unit 1505 of the third type may have a boundary of a second type of the gate cut region 626 shared with another cell to the right side thereof.

FIG. 16 is a demonstrative illustration of cross-sectional view of a semiconductor structure having a second combination of cells according to another embodiment of present invention. More particularly, embodiments of present invention provide a semiconductor structure 30 with a cell unit 1601 of a first type, a cell unit 1602 of a third type, a cell unit 1603 of a second type, a cell unit 1604 of a first type, and a cell unit 1605 of a first type. The five cells may be separated either by a first type of boundary made of a first type of gate cut region 631, 634, or 635 of a first width W1 or by a second type of boundary made of a second type of gate cut region 632, 633, or 636 of a second width W2.

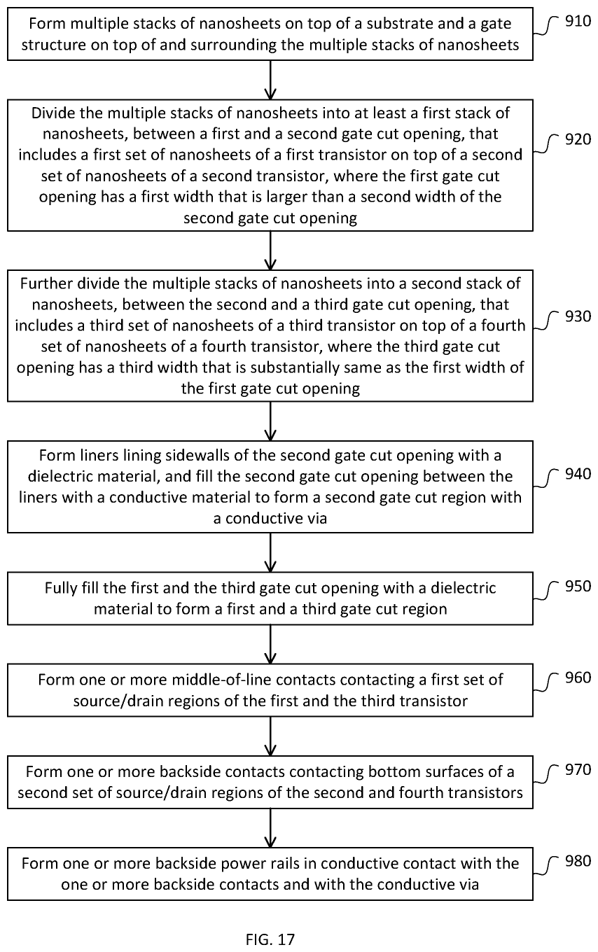

FIG. 17 is a demonstrative illustration of a flow-chart of a method of manufacturing a semiconductor structure according to embodiments of present invention. The method includes (910) forming multiple stacks of nanosheets on top of a substrate and a gate structure on top of and surrounding the multiple stacks of nanosheets; (920) forming a first and a second gate cut opening to divide the multiple stacks of nanosheets into at least a first stack of nanosheets, between the first and the second gate cut opening, that includes a first set of nanosheets of a first transistor on top of a second set of nanosheets of a second transistor, where the first gate cut opening has a first width that is larger than a second width of the second gate cut opening; (930) further forming a third gate cut opening to divide the multiple stacks of nanosheets into a second stack of nanosheets, between the second and the third gate cut opening, that includes a third set of nanosheets of a third transistor on top of a fourth set of nanosheets of a fourth transistor, where the third gate cut opening has a third width that is substantially same as the first width of the first gate cut opening; (940) forming liners lining sidewalls of the second gate cut opening with a dielectric material, and filling the second gate cut opening between the liners with a conductive material to form a second gate cut region with a conductive via; (950) fully filling the first and the third gate cut opening with a dielectric material to form a first and a third gate cut region; (960) forming one or more middle-of-line contacts contacting a first set of source/drain regions of the first and the third transistor; (970) forming one or more backside contacts contacting bottom surfaces of a second set of source/drain regions of the second and fourth transistors; and (980) forming one or more backside power rails in conductive contact with the one or more backside contacts and in conductive contact with the conductive via.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising a cell unit, the cell unit comprising:
a first field-effect-transistor (FET) stacked on top of a second FET;
a first cell boundary made of a first gate cut region with a first width; and
a second cell boundary made of a second gate cut region with a second width,
wherein the second width of the second gate cut region is wider than the first width of the first gate cut region.

2. The semiconductor structure of claim 1, wherein the cell unit is a first cell unit, further comprising a second cell unit, the second cell unit comprising:
a third FET stacked on top of a fourth FET; and
a third cell boundary made of the second gate cut region with the second width; and
a fourth cell boundary made of a third gate cut region with a third width,
wherein the third width of the third gate cut region is substantially same as the first width of the first gate cut region and is narrower than the second width of the second gate cut region, and wherein the first cell unit and the second cell unit has a same cell height.

3. The semiconductor structure of claim 2, wherein a source/drain (S/D) region of the first FET and a S/D region of the third FET are mirror-symmetry with respect to the second gate cut region, and a S/D region of the second FET and a S/D region of the fourth FET are mirror-symmetry with respect to the second gate cut region.

4. The semiconductor structure of claim 2, further comprising a conductive via formed inside the second gate cut region, wherein a source/drain (S/D) region of the first FET is conductively connected to a backside power rail by the conductive via, and the second gate cut region insulates the conductive via from the second FET and the fourth FET.

5. The semiconductor structure of claim 2, further comprising a conductive via formed inside the second gate cut region, wherein a source/drain (S/D) region of the second FET is conductively connected to a middle-of-line contact at a front side of the semiconductor structure, and the second gate cut region insulates the conductive via from the first FET and the third FET.

6. The semiconductor structure of claim 3, wherein the S/D region of the fourth FET is connected to a middle-of-line contact through a deep-via.

7. The semiconductor structure of claim 3, wherein the S/D region of the second FET is connected to a backside power rail through a backside contact.

8. The semiconductor structure of claim 2, wherein the first FET and the second FET are a first and a second nanosheet transistor having a first set of nanosheets and a second set of nanosheets respectively, and wherein a width of the first set of nanosheets is narrower than a width of the second set of nanosheets.

9. The semiconductor structure of claim 1, wherein the cell unit is a first cell unit, further comprising a second cell unit, the second cell unit comprising:
a third FET stacked on top of a fourth FET; and
a third cell boundary made of a third gate cut region with a third width; and
a fourth cell boundary made of the first gate cut region with the first width,
wherein the third width of the third gate cut region is substantially same as the first width of the first gate cut region, and wherein the first cell unit has a cell height that is smaller than a cell height of the second cell unit.

10. The semiconductor structure of claim 1, wherein the cell unit is a first cell unit, further comprising a second cell unit, the second cell unit comprising:
a third FET stacked on top of a fourth FET; and
a third cell boundary made of the second gate cut region with the second width; and
a fourth cell boundary made of a third gate cut region with a third width,
wherein the third width of the third gate cut region is substantially same as the second width of the second gate cut region and is wider than the first width of the first gate cut region, and wherein the first cell unit has a cell height that is larger than a cell height of the second cell unit.

11. A semiconductor structure comprising:
a first cell unit, the first cell unit comprising:
a first set of field-effect-transistors (FETs);
a first cell boundary made of a first gate cut region with a first width; and
a second cell boundary made of a second gate cut region with a second width,
a second cell unit, the second cell unit comprising:
a second set of FETs;
a third cell boundary made of a third gate cut region with a third width, the third width being substantially same as the first width; and
a fourth cell boundary made of the first gate cut region with the first width, and
a third cell unit, the third cell unit comprising:
a third set of FETs;
a fifth cell boundary made of the second gate cut region with the second width; and
a sixth cell boundary made of a fourth gate cut region with a fourth width, the fourth width being substantially same as the second width,
wherein the second width of the second gate cut region and the fourth width of the fourth gate cut region are wider than the first width of the first gate cut region and the third width of the third gate cut region.

12. The semiconductor structure of claim 11, wherein a cell height of the first cell unit is smaller than a cell height of the second cell unit and larger than a cell height of the third cell unit.

13. The semiconductor structure of claim 11, wherein the first gate cut region and the third gate cut region are made of a dielectric material, wherein the first set of FETs includes a top source/drain (S/D) region of a top FET and a bottom S/D region of a bottom FET, and wherein at least the second gate cut region includes a conductive via extending at least from a top surface of the top S/D region of the top FET to a bottom surface of the bottom S/D region of the bottom FET.

14. The semiconductor structure of claim 11, wherein the first set of FETs includes a first set of nanosheets on top of a second set of nanosheets, the first set of nanosheets having a width narrower than a width of the second set of nanosheets, and wherein the third set of FETs includes a fifth set of nanosheets on top of a sixth set of nanosheets, the fifth set of nanosheets having a width that is substantially same as a width of the sixth set of nanosheets.

15. A method of forming a semiconductor structure comprising:
forming multiple stacks of nanosheets on top of a substrate and a gate structure on top of and surrounding the multiple stacks of nanosheets;
cutting the gate structure to create at least a first gate cut opening and a second gate cut opening, and dividing the multiple stacks of nanosheets into at least a first stack of nanosheets between the first gate cut opening and the second gate cut opening, wherein the first stack of nanosheets includes a first set of nanosheets of a first transistor on top of a second set of nanosheets of a second transistor, and wherein the first gate cut opening has a first width and the second gate cut opening has a second width with the second width being larger than the first width;
forming a first gate cut region by depositing a dielectric material to fully fill the first gate cut opening;
forming liners lining sidewalls of the second gate cut opening with the dielectric material; and
forming a second gate cut region by filling the second gate cut opening between the liners with a conductive material, the conductive material forming a conductive via.

16. The method of claim 15, wherein cutting the gate structure further comprises:
creating a third gate cut opening and dividing the multiple stacks of nanosheets into a second stack of nanosheets between the second gate cut opening and the third gate cut opening, wherein the second stack of nanosheets includes a third set of nanosheets of a third transistor on top of a fourth set of nanosheets of a fourth transistor, and wherein the third gate cut opening has a third width that is substantially same as the first width of the first gate cut opening; and
forming a third gate cut region by depositing the dielectric material to fully fill the third gate cut opening.

17. The method of claim 16, wherein a source/drain (S/D) region of the first transistor and a S/D region of the third transistor are mirror-symmetry with respect to the second gate cut region, and a S/D region of the second transistor and a S/D region of the fourth transistor are mirror-symmetry with respect to the second gate cut region.

18. The method of claim 16, wherein cutting the gate structure further comprises:
creating a fourth gate cut opening and dividing the multiple stacks of nanosheets into a third stack of nanosheets between the fourth gate cut opening and the first gate cut opening, wherein the thick stack of nanosheets includes a fifth set of nanosheets of a fifth transistor on top of a sixth set of nanosheets of a sixth transistor, and wherein the fourth gate cut opening has a fourth width that is substantially same as the first width of the first gate cut opening; and
forming a fourth gate cut region by depositing the dielectric material to fully fill the fourth gate cut opening.

19. The method of claim 18, wherein a first cell unit having the first stack of nanosheets has a first cell height; a second cell unit having the second stack of nanosheets has a second cell height; and a third cell unit having the third stack of nanosheets has a third cell height, and wherein the first cell height is substantially same as the second cell height and is smaller than the third cell height.

20. The method of claim 16, further comprising:
forming one or more middle-of-line contacts contacting a first set of source/drain regions of the first and the third transistor;
forming one or more backside contacts contacting bottom surfaces of a second set of source/drain regions of the second and the fourth transistor; and
forming one or more backside power rails in conductive contact with the one or more backside contacts and in conductive contact with the conductive via.
